(19) United States
(12) Patent Application Publication
(10) Pub. No.: US 2013/0087183 A1
(43) Pub. Date: Apr. 11, 2013

(54) SOLAR CELL MODULE, AND SOLAR ENERGY GENERATOR DEVICE COMPRISING THE SOLAR CELL MODULE

(71) Applicant: Tsuyoshi Maeda, Osaka-shi (JP)

(72) Inventor: Tsuyoshi Maeda, Osaka-shi (JP)

(73) Assignee: SHARP KABUSHIKI KAISHA, Osaka-shi, Osaka (JP)

(21) Appl. No.: 13/704,440

(22) PCT Filed: Apr. 14, 2011
(86) PCT No.: PCT/JP2011/059293

§ 371 Date: Dec. 14, 2012

(30) Foreign Application Priority Data
Jun. 17, 2010 (JP) 2010-138677

(51) Int. Cl. H01L 31/055

(52) U.S. Cl. CPC H01L 31/055
USPC 136/247

(57) ABSTRACT

A solar cell module (1) disclosed herein includes a solar cell (2), a fluorescence condensing plate (3), and a reflecting plate (4). The solar cell (2) is provided on at least a portion of at least one of end surfaces (that is, intersecting surfaces each intersecting with a light-obtaining surface) of the fluorescence condensing plate (3). At least one of two mutually opposite portions on each of which the solar cell (2) is absent has a bent surface. The reflecting plate (4) is provided on a surface of a portion on which the solar cell (2) is absent. With this arrangement, light that is guided toward any flat section or zigzag section on which the solar cell (2) is not placed is reflected by the reflecting plate (4) to ultimately reach the solar cell (2).

### TECHNICAL FIELD

The present invention relates to (i) a solar cell module and (ii) a solar energy generator device including the solar cell module.

### BACKGROUND ART

Solar cells have been recognized for its importance as a clean energy source. There is thus a growing demand for them. Solar cells find a wide range of applications from a power energy source for large equipment to a compact power supply for precision electronic devices. Various solar energy generator devices including solar cells are increasingly in widespread use.

FIG. 9 illustrates an example of how a conventional solar energy generator device is used. As illustrated in FIG. 9, a common solar energy generator device 20 in current use is used with solar panels 21 so aligned flush with one another and adjacently to one another as to face the sun in order to utilize solar energy efficiently. Such solar panels 21 normally include an opaque semiconductor, and thus cannot be stacked on one another. This indicates that sufficiently collecting sunlight 26 requires a solar panel 21 having a large area, which in turn requires a large area for installation of the solar energy generator device 20.

In view of the above problem, Patent Literature 1 discloses a technique for reducing the area necessary for a solar energy generator device. Specifically, Patent Literature 1 discloses a solar energy generator device provided with a solar cell that is attached to a side surface of a light transparent absorbing/emitting plate containing a fluorescent substance dispersed therein, the side surface being orthogonal to a light-obtaining surface of the absorbing/emitting plate. This solar energy generator device is further provided with a reflecting layer at each side surface other than the side surface to which the solar cell is attached. With this arrangement, in the case where the light absorbing/emitting plate is used as a window surface of a structure, sunlight that has entered the absorbing/emitting plate through the light-obtaining surface is guided through the light absorbing/emitting plate to be condensed upon the solar cell. The above arrangement thus makes it possible to utilize solar energy efficiently with use of a solar energy generator device having a small area.

### CITATION LIST

### Patent Literature 1

Japanese Utility Model Application Publication, Jitsukaishou, No. 61-136559 A (Publication Date: Aug. 25, 1986)

### SUMMARY OF INVENTION

### Technical Problem

In the case where a solar cell is placed on an edge of a transparent fluorescent screen as in the solar energy generator device disclosed in Patent Literature 1, it is possible to reduce the area for the solar energy generator device. Such a solar energy generator device is, however, low in sunlight use efficiency. The description below deals with this point with reference to FIG. 10. FIG. 10 is a view schematically illustrating a solar energy generator device 30 of Patent Literature 1 as viewed toward its light-obtaining surface.

Of light that has fallen onto the light-obtaining surface of the solar energy generator device 30, incident light 36 that has been guided perpendicularly to an end surface on which a solar cell 32 is not provided (see FIG. 10) is merely repeatedly reflected by a reflecting plate 34 between the above end surface and an end surface opposite thereto, and thus cannot be condensed upon the solar cell 32. As a result, light that has been guided perpendicularly to an end surface on which the solar cell 32 is not provided does not enter the solar cell 32, which decreases light use efficiency of the solar energy generator device 30.

The present invention has been accomplished in view of the above problem. It is an object of the present invention to provide (i) a solar cell module that is capable of generating electric power highly efficiently by condensing external light upon a solar cell efficiently and (ii) a solar energy generator device including the solar cell module.

### Solution to Problem

In order to solve the above problem, a solar cell module of the present invention includes: a condensing plate containing a fluorescent material, the condensing plate having (i) a light-obtaining surface and (ii) a plurality of intersecting surfaces each intersecting with the light-obtaining surface; and a solar cell provided on at least a first portion of at least one of the plurality of intersecting surfaces, a reflecting plate being provided on a portion of the plurality of intersecting surfaces which portion is other than the first portion, at least a first part being present in which portions on each of which the solar cell is absent are opposite to each other, at least one of any two mutually opposite portions selected from the first part having a bent surface.

According to the above arrangement, (i) a solar cell is provided on at least a portion of end surfaces (that is, intersecting surfaces each intersecting with a light-obtaining surface) of a condensing plate, and (ii) at least one of two mutually opposite portions on each of which the solar cell 2 is absent has a bent surface. With this arrangement, light that is guided toward any portion on which the solar cell is not placed is reflected by a reflecting plate to ultimately reach the solar cell for utilization in electric power generation by the solar cell. In particular, light that has been guided to the bent surface of the condensing plate is reflected by that surface in a direction shifted from the direction of regular reflection. With this arrangement, almost all light that has been guided through the condensing plate ultimately reaches the solar cell, which increases light condensing property of the solar cell module.

If two mutually opposite end surfaces on each of which the solar cell is absent each have a flat section and are disposed parallel to each other, a portion of incident light that has entered the condensing plate which portion has been guided along the direction perpendicular to either of two end surfaces disposed parallel to each other will merely be repeatedly reflected between the two end surfaces disposed parallel to each other, and will not enter the solar cell. In this regard, according to the condensing plate of the present invention, at least one of two mutually opposite portions on each of which the solar cell is absent has a bent surface. This arrangement prevents light from being repeatedly reflected between two end surfaces. With the above arrangement, most incident light that has entered the solar cell module can be condensed onto the solar cell, which increases electric power generation efficiency of the solar cell module.

The solar cell is provided on an end surface of the condensing plate. This arrangement allows sufficient efficiency in electric power generation even with use of a solar cell having a small area. Further, the solar cell module has a design that has a high degree of freedom. This allows the solar cell module to be attached to (i) a window frame of a structure or automobile for use or (ii) onto a roof for use, thus making it possible to provide a solar energy generator system having high efficiency.

In order to solve the above problem, a solar energy generator device of the present invention includes the solar cell module described above.

The above arrangement makes it possible to provide a solar energy generator device that is capable of converting sunlight energy into electric power efficiently with use of a solar cell having a small area.

For a fuller understanding of the nature and advantages of the invention, reference should be made to the ensuing detailed description taken in conjunction with the accompanying drawings.

### Advantageous Effects of Invention

The present invention makes it possible to (i) condense, onto a solar cell, most external light that has entered a solar cell module, and thus (ii) increase electric power generation efficiency of the solar cell module. Further, a solar cell is provided on an end surface of a condensing plate. This arrangement makes it possible to achieve sufficient electric power generation efficiency even with use of a solar cell having a small area. In addition, the solar cell module has a design that has a high degree of freedom. This allows the solar cell module to be attached to (i) a window frame of a structure or automobile for use or (ii) onto a roof for use, thus making it possible to provide a solar energy generator system having high efficiency.

### BRIEF DESCRIPTION OF DRAWINGS

FIG. 1

FIG. 1 is a diagram illustrating a solar cell module of an embodiment of the present invention as viewed toward a light-obtaining surface.

FIG. 2

FIG. 2 is a diagram illustrating a solar cell module of an embodiment of the present invention as viewed toward a light-obtaining surface.

FIG. 3

(a) is a diagram schematically illustrating a cross section of a fluorescence condensing plate of an embodiment of the present invention, (b) is a diagram schematically illustrating a cross section of a fluorescence condensing plate of an embodiment of the present invention, (c) is a diagram schematically illustrating a cross section of a fluorescence condensing plate of an embodiment of the present invention, and (d) is a diagram schematically illustrating a cross section of a fluorescence condensing plate of an embodiment of the present invention.

FIG. 4

(a) is a diagram illustrating a cross section of a zigzag section in a fluorescence condensing plate of an embodiment of the present invention, (b) is a diagram illustrating a cross section of a zigzag section in a fluorescence condensing plate of an embodiment of the present invention, (c) is a diagram illustrating a cross section of a zigzag section in a fluorescence condensing plate of an embodiment of the present invention, and (d) is a diagram illustrating a cross section of a zigzag section in a fluorescence condensing plate of an embodiment of the present invention.

FIG. 5

FIG. 5 is a diagram illustrating a solar cell module including a fluorescence condensing plate that includes a zigzag section having a bent portion with a bend angle of 90 degrees.

FIG. 6

FIG. 6 is a perspective diagram illustrating a fluorescence condensing plate of an embodiment of the present invention.

FIG. 7

FIG. 7 is a diagram illustrating a solar cell module of an embodiment of the present invention as viewed toward a light-obtaining surface.

FIG. 8

FIG. 8 is a diagram illustrating a solar cell module including a fluorescence condensing plate in which an end surface on which a solar cell is placed and an end surface opposite to the above end surface are formed of flat sections that are parallel to each other.

FIG. 9

FIG. 9 is a view illustrating an example of how a conventional solar energy generator device is used.

FIG. 10

FIG. 10 is a diagram illustrating a conventional solar energy generator device as viewed toward a light-obtaining surface.

### DESCRIPTION OF EMBODIMENTS

The description below deals in detail with an embodiment of the present invention with reference to the drawings.

### First Embodiment

(Arrangement of Solar Cell Module 1)

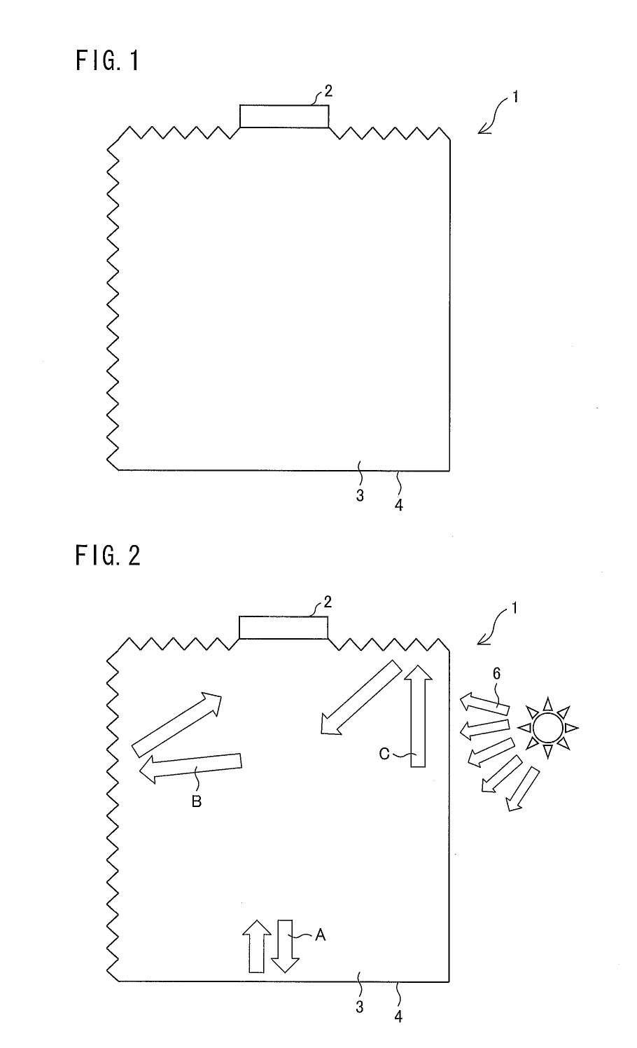

The description below first deals with a first embodiment of a solar cell module of the present invention with reference to FIG. 1. FIG. 1 is a diagram illustrating a solar cell module 1 as viewed toward a light-obtaining surface.

As illustrated in FIG. 1, the solar cell module 1 includes: a solar cell 2; a fluorescence condensing plate 3 (condensing plate); and a reflecting plate 4. The fluorescence condensing plate 3 is in the shape of a plate, and has (i) a light-obtaining surface on which external light such as sunlight and illumination light falls and (ii) intersecting surfaces (that is, end surfaces or side surfaces) each intersecting with the light-obtaining surface. The solar cell 2 is provided on at least a portion of at least one of the end surfaces of the fluorescence condensing plate 3. The end surfaces include a portion on which the solar cell 2 is not provided, the portion including (i) a section (hereinafter referred to as “flat section”) having a flat surface and (ii) a section (hereinafter referred to as “zigzag section”) having a bent surface. Specifically, at least one of two mutually opposite portions on which the solar cell 2 is not provided simply needs to include a zigzag section. In other words, at least one of any two mutually opposite portions selected from a part at which portions on which the solar cell 2 is not provided are mutually opposite to each other includes a zigzag section. The flat section and the zigzag section are provided with the reflecting plate 4. FIG. 1 illustrates a configuration in which (i) the solar cell 2 is provided on a portion of one of the end surfaces of the fluorescence condensing plate 3 and (ii) the remaining portion of the end surface on which remaining portion the solar cell 2 is not provided includes a zigzag section. Further, two of the other three end surfaces each include a flat section, and the remaining end surface includes a zigzag section. The flat sections and the zigzag sections on which the solar cell 2 is not provided are provided with the reflecting plate 4.

Light that has entered the solar cell module 1 through the light-obtaining surface is guided through the inside of the fluorescence condensing plate 3 to be ultimately condensed onto the solar cell 2. Such condensed light is utilized for electric power generation by the solar cell 2. The solar cell module 1 of the present embodiment is characterized in that the fluorescence condensing plate 3 has end surfaces that include a flat section and a zigzag section as described above. Note that the flat sections on which the solar cell 2 is not provided are located not to be opposite to each other. In other words, at least one of two mutually opposite portions on which the solar cell 2 is not provided includes a zigzag section. With this arrangement, most light that has entered the solar cell module 1 is condensed onto the solar cell 2, thus allowing the solar cell module 1 to generate electric power efficiently. The description below deals with this arrangement with reference to FIG. 2. FIG. 2 is a diagram illustrating the solar cell module 1 as viewed toward the light-obtaining surface.

As illustrated in FIG. 2, the sun or an illumination device, for example, irradiates the light-obtaining surface of the solar cell module 1, so that incident light 6 such as sunlight or illumination light falls onto the light-obtaining surface. The fluorescence condensing plate 3 absorbs such incident light 6 that has entered it and emits fluorescence light. Of light that has been emitted by the fluorescence condensing plate 3, light that has been guided along, for example, the directions indicated by the arrows A illustrated in FIG. 2 is reflected by the reflecting plate 4 to enter the solar cell 2. On the other hand, light that has been guided along the directions indicated by the arrows B and C is reflected by the reflecting plate 4 in, due to the zigzag sections of the end surfaces of the fluorescence condensing plate 3, directions shifted from the direction of regular reflection, and ultimately enters the solar cell 2. If two mutually opposite end surfaces on each of which the solar cell 2 is absent are each formed of a flat section and are disposed parallel to each other, a portion of the incident light 6 that has entered the fluorescence condensing plate 3 which portion has been guided along the direction perpendicular to either of two end surfaces disposed parallel to each other will merely be repeatedly reflected between the two end surfaces disposed parallel to each other, and will not enter the solar cell 2. In this regard, the fluorescence condensing plate 3 of the present embodiment includes flat sections and zigzag sections on a surface of a portion at which the solar cell 2 is not provided. the flat sections being so disposed as not to be opposite to each other. This arrangement prevents light from being repeatedly reflected between two end surfaces. With the above arrangement, most incident light 6 that has entered the solar cell module 1 can be condensed onto the solar cell 2, which increases electric power generation efficiency of the solar cell module 1.

The present invention has been accomplished in order to prevent occurrence of light that is repeatedly reflected between two end surfaces of the fluorescence condensing plate 3 on which end surfaces the solar cell 2 is not provided. It is thus needless to say that the present embodiment is applicable to the case in which the fluorescence condensing plate 3 has a plurality of end surfaces on which the solar cell 2 is not provided. It is also evident that the present embodiment is applicable to the case in which the plurality of end surfaces of the fluorescence condensing plate 3 at least include a part at which portions of respective end surfaces on which the solar cell 2 is not provided are opposite to each other.

(Individual Members of Solar Cell Module 1)

The description below deals with a detailed arrangement of the solar cell module 1.

The fluorescence condensing plate 3 converts the wavelength of light that has entered the fluorescence condensing plate 3 so that the wavelength falls within a range effective in photoelectric conversion by the solar cell 2. The fluorescence condensing plate 3 is, however, simply required to (i) guide light that has entered the fluorescence condensing plate 3 through the light-obtaining surface and thus (ii) cause such light to be condensed onto the solar cell 2 provided on an end surface. Such a fluorescence condensing plate 3 is, for example, a light guide plate containing a fluorescent material or a light guide plate to which a fluorescent material has been applied. Specifically, the above fluorescent material can be a fluorescent material that has been publicly known, and examples of the fluorescent material include, but are not limited to, (i) a coumarin fluorescence pigment, (ii) a hydrochloride or sulfate of a rare-earth metal such as samarium, terbium, europium, gadolinium, and dysprosium, (iii) a transition metalate such as calcium molybdate and calcium tungstate, (iv) an aromatic hydrocarbon such as benzene and naphthalene, and (v) a phthalein pigment such as cosine and fluorescein. The above light guide plate can be a light guide plate that has been publicly known, and examples of the light guide plate include, but are not limited to, an acrylic substrate, a glass substrate, and a polycarbonate substrate.

The above fluorescent material contained in the fluorescence condensing plate 3 is not particularly limited in content. The content is, however, preferably not greater than 10 weight %. This arrangement prevents multiple scattering caused by the fluorescent material, and thus allows fluorescence to be emitted efficiently.

The fluorescence condensing plate 3 is not particularly limited in thickness. The thickness, however, preferably falls within the range from 1 mm to 10 mm, or more preferably falls within the range from 2 mm to 5 mm. This arrangement allows production of a lightweight but strong fluorescence condensing plate 3. Further, the length of a side of the fluorescence condensing plate 3 is not particularly limited. The area of the fluorescence condensing plate 3 on the light-obtaining surface is not particularly limited as well.

In the case where the solar cell module 1 is attached to a window frame of a structure for use, the fluorescence condensing plate 3 is attachable to the window frame, and includes, for example, an acrylic substrate having a size and thickness that allow the acrylic substrate to function as a window surface. In the case where the solar cell module 1 is disposed onto a roof for use, the size and thickness of the fluorescence condensing plate 3 may be set as appropriate in correspondence with conditions such as an installation area.

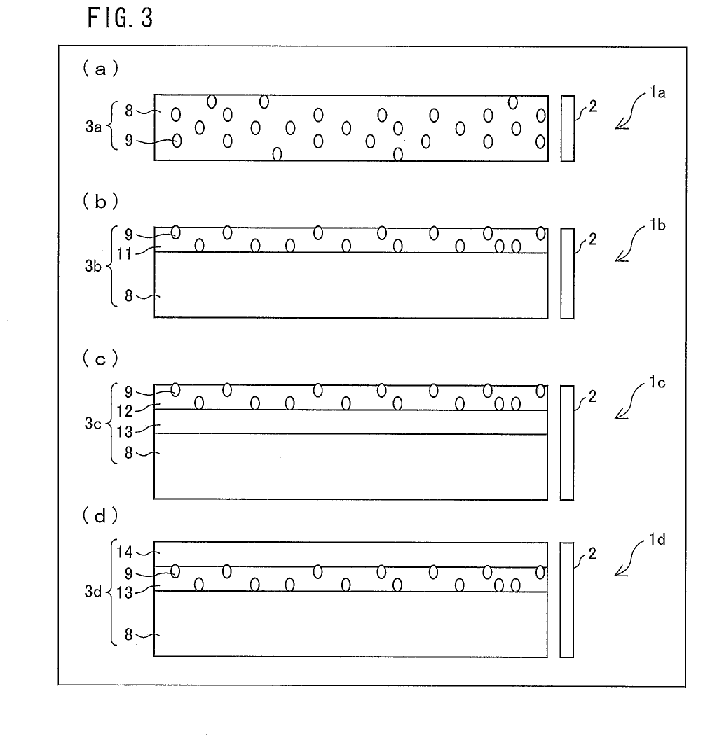

The fluorescence condensing plate 3 is produced by, for example, any of the four methods below. The description below deals with those production methods with reference to FIG. 3. (a) through (d) of FIG. 3 are diagrams schematically illustrating respective cross sections of fluorescence condensing plates 3a through 3d. (a) through (d) of FIG. 3 each omit depiction of the reflecting plate 4 to clearly illustrate the fluorescence condensing plates 3a through 3d.

The description below first deals with a fluorescent material dispersion method. This method, as illustrated in (a) of FIG. 3, prepares a fluorescence condensing plate 3a by dispersing a fluorescent material 9 in a light guide plate 8. The method then (i) provides the solar cell 2 to a part of an end surface of the fluorescence condensing plate 3a prepared as above and (ii) forms a flat section and a zigzag section at portions on which the solar cell 2 is not provided. The method next provides a reflecting plate 4 to the flat section and zigzag section on which the solar cell 2 is not provided. This operation completes preparation of a solar cell module 1a.

The description below next deals with a fluorescent material coating method. This method, as illustrated in (b) of FIG. 3, prepares a fluorescence condensing plate 3b by applying, to a surface of a light guide plate 8, a coating agent 11 containing a fluorescent material 9 dispersed therein. The method then (i) provides the solar cell 2 to a part of an end surface of the fluorescence condensing plate 3b prepared as above and (ii) forms a flat section and a zigzag section at portions on which the solar cell 2 is not provided. The method next provides a reflecting plate 4 to the flat section and zigzag section on which the solar cell 2 is not provided. This operation completes preparation of a solar cell module 1b.

The description below now deals with a fluorescent sheet attaching method. This method, as illustrated in (c) of FIG. 3, prepares a fluorescence condensing plate 3c by attaching, to a light guide plate 8 with an adhesive 13 in-between, a sheet 12 containing a fluorescent material 9 dispersed therein. The method then (i) provides the solar cell 2 to a part of an end surface of the fluorescence condensing plate 3c prepared as above and (ii) forms a flat section and a zigzag section at portions on which the solar cell 2 is not provided. The method next provides a reflecting plate 4 to the flat section and zigzag section on which the solar cell 2 is not provided. This operation completes preparation of a solar cell module 1c.

The description below next deals with a fluorescent agglutinant attaching method. This method, as illustrated in (d) of FIG. 3, prepares a fluorescence condensing plate 3d by (i) dispersing a fluorescent material 9 in an adhesive 13 and (ii) attaching a transparent sheet 14 to a light guide plate 8 with the adhesive 13 in-between. The method then (i) provides the solar cell 2 to a part of an end surface of the fluorescence condensing plate 3d prepared as above and (ii) forms a flat section and a zigzag section at portions on which the solar cell 2 is not provided. The method next provides a reflecting plate 4 to the flat section and zigzag section on which the solar cell 2 is not provided. This operation completes preparation of a solar cell module 1d.

The fluorescence condensing plate 3 of the present embodiment can be produced by any of the above production methods. The fluorescence condensing plate 3 is, however, not necessarily produced by one of the above production methods.

The reflecting plate 4 can be a publicly known reflecting plate. Examples of the reflecting plate 4 include, but are not limited to, an aluminum reflecting plate, a silver (Ag) reflecting plate, and a dielectric laminate film. The reflecting plate 4 is not particularly limited in size. The reflecting plate 4, however, preferably has an attachment surface having a width that is equal to the thickness of the fluorescence condensing plate 3. This arrangement makes it possible to efficiently reflect light that is guided through the fluorescence condensing plate 3 to reach an end surface of the fluorescence condensing plate 3 on which end surface the reflecting plate 4 is provided.

The solar cell 2 can be a publicly known solar cell. Examples of the solar cell 2 include, but are not limited to, an amorphous silicon (a-Si) solar cell, a polycrystalline silicon solar cell, a monocrystalline silicon solar cell, and a compound solar cell. The solar cell 2 is attached to an end surface of the fluorescence condensing plate 3 with use of, for example, a light-transmitting adhesive that has been publicly known. The solar cell 2 is not particularly limited in size. The solar cell 2, however, preferably includes a light receiving section having a width that is equal to the thickness of the fluorescence condensing plate 3. This arrangement makes it possible to efficiently receive light that is guided through the fluorescence condensing plate 3 to reach an end surface of the fluorescence condensing plate 3 on which end surface the solar cell 2 is provided.

A solar cell module 1 as illustrated in FIG. 1 was produced and examined for its electric power generation efficiency. First, a coumarin fluorescence pigment that would emit light in response to sunlight was dispersed in acrylic resin in an amount of approximately 3 weight % to prepare a rectangular fluorescence condensing plate 3 having a thickness of 10 mm and an area of 1 m² (1 m×1 m) on its light-obtaining surface. Then, the fluorescence condensing plate 3 thus prepared was provided with, on a portion of an end surface thereof, a solar cell 2 including a light receiving section having a width of 10 mm. Zigzag sections (bend angle: approximately 110 degrees; pitch of a concave bent portion: 2 cm) were formed in respective portions of end surfaces on which portions the solar cell 2 was not provided. More specifically, a zigzag section was formed in each of (i) a portion of the end surface on which the solar cell 2 was placed on which portion the solar cell 2 was absent and (ii) an end surface (corresponding to the left side of the fluorescence condensing plate 3 illustrated in FIG. 1) orthogonal to the end surface on which the solar cell 2 was placed. Then, an aluminum reflecting plate serving as the reflecting plate 4 was bonded with use of an acrylic adhesive to (i) a flat section on which the solar cell 2 was not provided and (ii) the zigzag section. The solar cell module 1 thus produced generated, when placed outdoors under cloudless skies, electric power in an amount of approximately 8 W.

To compare with the above solar cell module 1, a square fluorescence condensing acrylic plate having a thickness of 10 mm and a size of 1 m×1 m was produced with use of materials similar to those used to produce the above solar cell module 1. A solar cell including a light receiving section having a width of 10 mm was provided to a portion (approximately 30 cm) of an end surface of the prepared fluorescence condensing acrylic plate. Then, an aluminum reflecting plate was bonded with use of an acrylic adhesive to (i) a portion of the end surface on which the solar cell was placed on which portion the solar cell was absent and (ii) the other end surfaces. The solar cell module thus produced generated, when placed outdoors under cloudless skies, electric power in an amount of approximately 6 W.

As described above, the solar cell module 1 of the present embodiment is higher in electric power generation efficiency than conventional solar cell modules. This is because the solar cell module 1 is higher in light condensing rate than conventional solar cell modules. Specifically, when the solar cell module 1 is irradiated with sunlight, (i) a portion of the sunlight which portion has a wavelength that falls within a certain range is absorbed by a fluorescent substance present in the acrylic resin, and (ii) the fluorescent substance emits light having a wavelength that falls within a yellowish green range. The solar cell 2 utilizes, for electric power generation, a portion (approximately 75%) of the yellowish green light which portion is guided through the fluorescence condensing plate 3 directly to a portion of the end surface on which the solar cell 2 is placed on which portion the solar cell 2 present. On the other hand, light that is guided to (i) a portion of the end surface on which the solar cell 2 is placed on which portion the solar cell 2 is absent and (ii) any of the three end surfaces on which the solar cell 2 is not placed is reflected by the reflecting plate 4, and ultimately reaches the solar cell 2 to be utilized for electric power generation by the solar cell 2. In particular, light that has been guided to a zigzag section of the fluorescence condensing plate 3 is reflected by that zigzag section in a direction shifted from the direction of regular reflection. With this arrangement, almost all light that has been guided through the fluorescence condensing plate 3 ultimately reaches the solar cell 2, which increases light condensing property of the solar cell module 1.

According to the solar cell module 1 of the present embodiment, the solar cell 2 is provided on an end surface of the fluorescence condensing plate 3. This arrangement allows sufficient efficiency in electric power generation even with use of a solar cell 2 having a small area. Further, the solar cell module 1 has a design with a high degree of freedom. This allows the solar cell module 1 to be attached to (i) a window frame of a structure or automobile for use or (ii) onto a roof for use, thus making it possible to provide a solar energy generator system having high efficiency.

(Example Shapes of Zigzag Section)

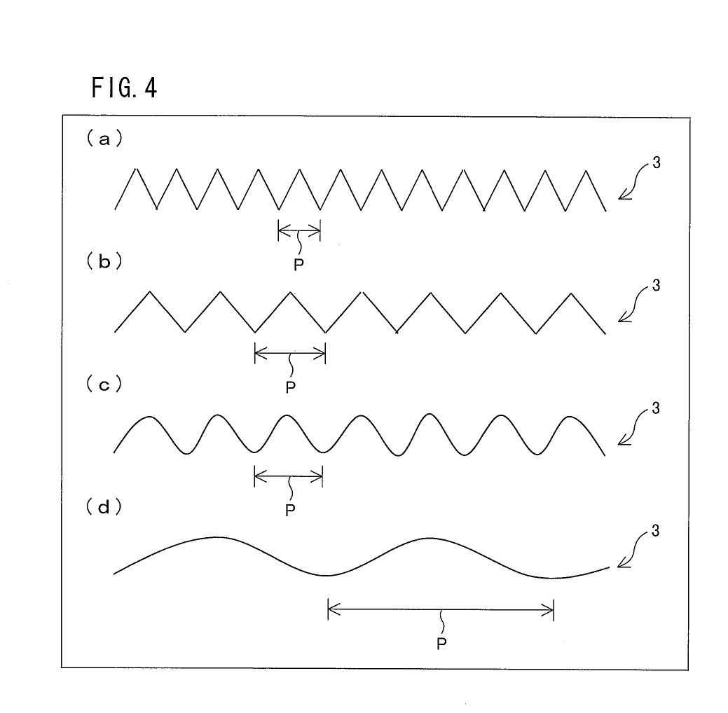

The zigzag section in the end surfaces of the fluorescence condensing plate 3 is not particularly limited in shape. The zigzag section can be a zigzag section having any of various shapes. The zigzag section may have, along a surface direction of the fluorescence condensing plate 3, a cross section in, for example, (i) a zigzag shape (that is, the zigzag section has a bent portion in a pointed shape) or (ii) in the shape of a wavy line (that is, the zigzag section has a bent portion in the shape of a round surface). FIG. 4 illustrates example shapes of a zigzag section in the end surfaces of the fluorescence condensing plate 3. (a) through (d) of FIG. 4 are each a diagram illustrating a cross-sectional shape of a zigzag section of the fluorescence condensing plate 3.

As illustrated in (a) and (b) of FIG. 4, the fluorescence condensing plate 3 includes a zigzag section having a concave bent portion that may have a narrow pitch P or a wide pitch P. In the fluorescence condensing plate 3 of the present embodiment, the concave bent portion of a zigzag section is not particularly limited in pitch P. The pitch P is, however, preferably not smaller than 1 μm. With this arrangement, light that has fallen onto the zigzag section is reflected so that the traveling direction of the light is changed. If the pitch P of a concave bent portion is smaller than the wavelength of light that is guided through the fluorescence condensing plate 3, the zigzag section will not be able to reflect such light. The fluorescence condensing plate 3 of the present embodiment thus includes a zigzag section having a concave bent portion with a pitch P that is larger than at least the wavelength of light that is guided through the fluorescence condensing plate 3.

The zigzag section may alternatively have a bent portion in the shape of a round surface as illustrated in (c) and (d) of FIG. 4. In the case where the zigzag section has a bent portion in the pointed shape, a portion of light that has entered the solar cell module 1 which portion has been guided to a bent portion of the zigzag section may be absorbed by that bent portion. This will unfortunately decrease light use efficiency of the solar cell module 1. In the case where, to prevent such decrease, the fluorescence condensing plate 3 includes a zigzag section having a bent portion in the shape of a round surface, a portion of light that has entered the solar cell module 1 which portion has been guided to a bent portion of the zigzag section included in the fluorescence condensing plate 3 is reflected by the round surface of that bent portion. This arrangement can thus prevent the above light, which has been guided to a bent portion of the zigzag section, from being absorbed by that bent portion. The above arrangement consequently allows the solar cell module 1 to be higher in light condensing property and in light use efficiency. The bent portion of the zigzag section included in the fluorescence condensing plate 3 is not particularly limited in radius of curvature. The radius of curvature, however, preferably falls within the range from 0.01 cm to 3.0 cm, or more preferably falls within the range from 0.1 cm to 0.5 cm. This arrangement advantageously secures an area for the light-obtaining surface, and facilitates attachment of the reflecting plate.

Not only the bent portion of the zigzag section but also a portion of the fluorescence condensing plate 3 at which portion two end surfaces meet (that is, each corner of the solar cell module 1) may be in the shape of a round surface. In addition to the above case, in the case where the fluorescence condensing plate 3 has end surfaces that form an angle together (that is, the solar cell module 1 has an angular corner), light that has entered the solar cell module 1 may be absorbed by a corner of the solar cell module 1 for a reason similar to the above.

In the case where, to prevent such light absorption, in the case where the solar cell module 1 has a corner in the shape of a round surface, a portion of light that has entered the solar cell module 1 which portion has been guided to a corner of the solar cell module 1 is reflected by the round surface of that corner. This arrangement can thus prevent the above light, which has been guided to a corner of the solar cell module 1, from being absorbed by that corner. The above arrangement consequently allows the solar cell module 1 to be higher in light condensing property and in light use efficiency.

In the above case, the reflecting plate 4 to be bonded to the fluorescence condensing plate 3 is not bonded to the individual end surfaces of the fluorescence condensing plate 3. Instead, the reflecting plate 4, in the above case, is in a belt shape and can be bonded to the side surfaces of the fluorescence condensing plate 3 by being continuously attached to the side surfaces. As described above, the reflecting plate 4 is more easily bonded to the end surfaces of the fluorescence condensing plate 3 in the case where (i) end surfaces to which the reflecting plate 4 is to be bonded meet at a portion that is in the shape of a round surface or (ii) the zigzag section has a bent portion in the shape of a round surface. Further, the above arrangement can prevent the solar cell module 1 from being cracked or chipped while, for instance, it is being forwarded, and consequently allows the solar cell module 1 to be handled more easily.

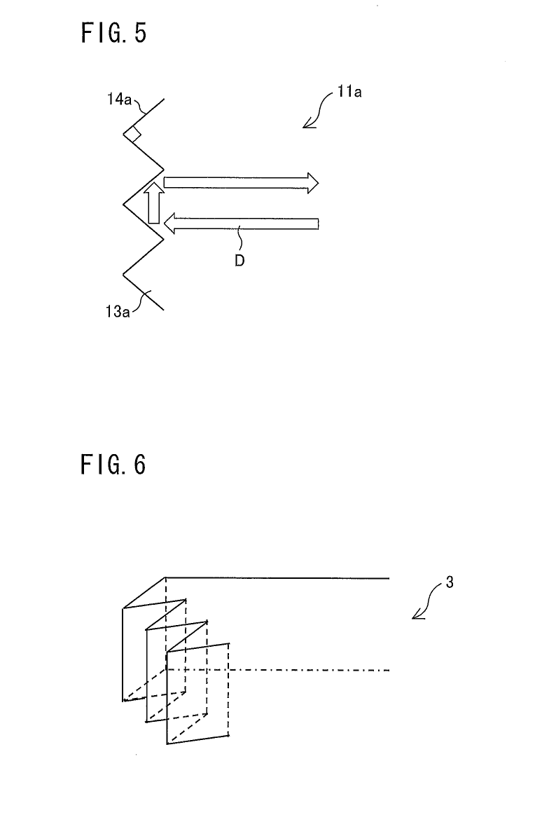

Further, the bent portion of the zigzag section in the fluorescence condensing plate 3 may have a bend angle with a small vertical angle or a large vertical angle as illustrated in (a) through (d) of FIG. 4. In the fluorescence condensing plate 3 of the present embodiment, the bent portion of a zigzag section is not particularly limited in bend angle. The bend angle, however, preferably falls within the range from 100 degrees to 120 degrees. With this arrangement, light that has fallen onto an end surface of the fluorescence condensing plate 3 at a wide angle can be reflected in the direction toward the position at which the solar cell 2 is placed. Note that in the case where the bent portion of a zigzag section has a bend angle of 90 degrees, light that has entered the solar cell module 1 cannot be guided to the solar cell 2 efficiently. The description below deals with this point with reference to FIG. 5. FIG. 5 is a diagram illustrating a solar cell module 11a including a fluorescence condensing plate 13a that includes a zigzag section having a bent portion with a bend angle of 90 degrees.

As illustrated in FIG. 5, in the case where the fluorescence condensing plate 13a includes a zigzag section having a bent portion with a bend angle of 90 degrees, light that has fallen upon the fluorescence condensing plate 13a along the direction indicated by the arrow D in FIG. 5 is reflected by a reflecting plate 14a. Such light is, however, reflected twice by the zigzag section of the fluorescence condensing plate 13a to travel along the direction opposite to the direction indicated by the arrow D. Thus, in the case where the zigzag section has a bent portion with a bend angle of 90 degrees, light that has fallen upon the fluorescence condensing plate 13a along the direction indicated by the arrow D is merely reflected by the reflecting plate 14a in the direction opposite to the direction indicated by the arrow D. The traveling direction of the light thus cannot be changed to a direction other than the direction indicated by the arrow D or the direction opposite thereto. This means that in the case where the zigzag section has a bent portion with a bend angle other than 90 degrees, the fluorescence condensing plate 13a will be able to (i) change even the traveling direction of light that has fallen upon the fluorescence condensing plate 13a along the direction indicated by the arrow D and thus (ii) guide such light to the solar cell 2 efficiently. Consequently, the zigzag section simply needs to have a bent portion with a bend angle of either (i) greater than 0 degrees and smaller than 90 degrees or (ii) greater than 90 degrees and smaller than 180 degrees.

(Example Shape of Fluorescence Condensing Plate 3)

The fluorescence condensing plate 3 is, as described above, in the shape of a plate, and has (i) a light-obtaining surface on which external light such as sunlight and illumination light falls and (ii) intersecting surfaces (that is, end surfaces or side surfaces) each intersecting with the light-obtaining surface. The fluorescence condensing plate 3 is, as illustrated in FIG. 6, preferably arranged such that the light-obtaining surface is substantially parallel to the surface opposite to the light-obtaining surface and that the end surfaces of the fluorescence condensing plate 3 are perpendicular to the light-obtaining surface. In other words, the end surfaces of the fluorescence condensing plate 3 preferably include a flat section and a zigzag section each of which is formed of a surface that is orthogonal to the light-obtaining surface.

The above arrangement does not disturb conditions under which light that has been guided through the fluorescence condensing plate 3 is totally reflected at the end surfaces (that is, a flat section and a zigzag section) of the fluorescence condensing plate 3. Thus, with the above arrangement, light that has entered the solar cell module 1 can be reflected by the reflecting plate 4, which is provided to the end surfaces of the fluorescence condensing plate 3, to be guided to the solar cell 2 efficiently.

(Example Disposition of Zigzag Section)

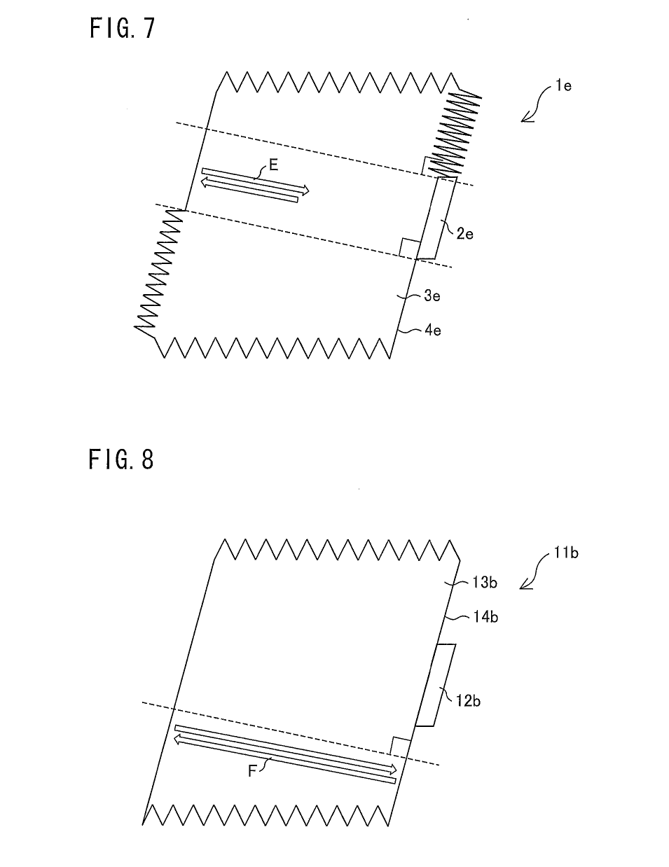

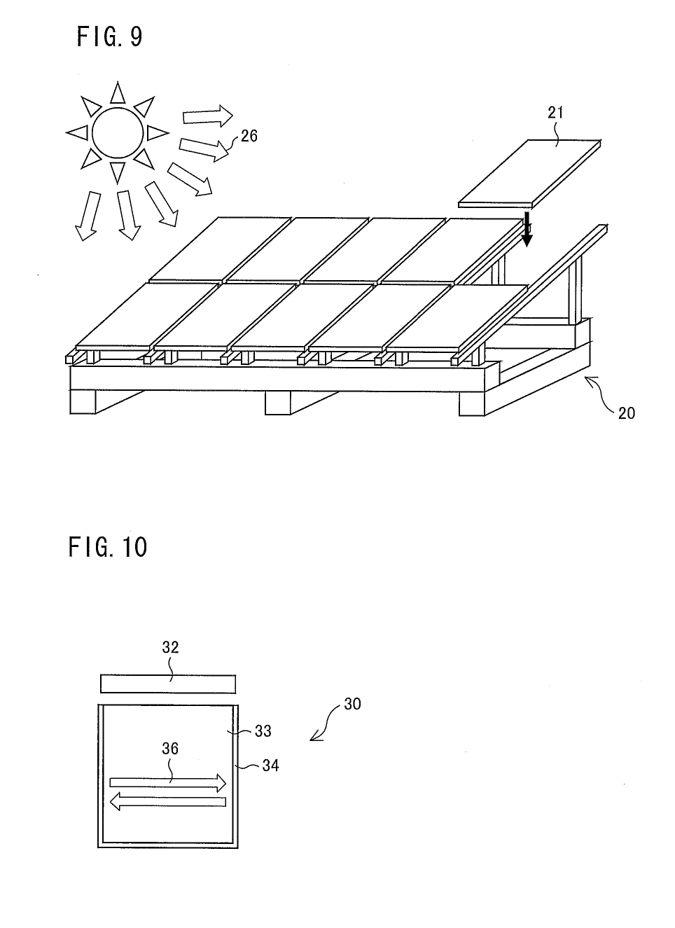

The shape of the fluorescence condensing plate 3 illustrated in FIG. 1 is merely an example. The fluorescence condensing plate 3 is thus not particularly limited in shape to such an example. For instance, the fluorescence condensing plate 3 may include both a flat section and a zigzag section at a single end surface. FIG. 7 illustrates an example shape of a fluorescence condensing plate 3 including a flat section and a zigzag section at a single end surface.

FIG. 7 illustrates a solar cell module 1e. The solar cell module 1e is provided with a solar cell 2 on an end surface. This end surface is opposite to an end surface having a portion that is opposite to the solar cell 2, and at least that portion is formed of a flat section. The solar cell module 1e of FIG. 7 is arranged such that (i) a portion that is opposite to the solar cell 2 is formed of a flat section and that a portion other than that flat section which portion is opposite to a flat section is formed of a zigzag section.

With the above arrangement, light that has fallen upon the solar cell module 1e along the direction (that is, the direction perpendicular to the end surface on which the solar cell 2 is placed) indicated by the arrow E in FIG. 7 is perpendicularly reflected by the flat section opposite to the solar cell 2, and is thus condensed upon the solar cell 2 efficiently. Specifically, light that has been perpendicularly reflected by the flat section opposite to the solar cell 2 reaches the solar cell 2 directly, that is, such light is guided to the solar cell 2 through a minimum light guide distance. The above arrangement can thus minimize absorption loss that occurs while light is guided.

Note that light that has entered the solar cell module 1e cannot be guided to the solar cell 2 efficiently if there are, other than the combination of (i) the portion on which the solar cell 2 is placed and (ii) the portion opposite to the solar cell 2, two mutually opposite flat sections that are parallel to each other. The description below deals with this point with reference to FIG. 8. FIG. 8 is a diagram illustrating a solar cell module 11b including a fluorescence condensing plate 13b in which an end surface on which a solar cell 12a is placed and an end surface opposite to the above end surface are formed of flat sections that are parallel to each other.

As illustrated in FIG. 8, light that has entered the solar cell module 11b along the direction (that is, the direction perpendicular to the end surface on which the solar cell 12b is placed) indicated by the arrow F is merely repeatedly reflected by a reflecting plate 14b (which is provided at the end surface opposite to the end surface on which the solar cell 12b is placed) between (i) the end surface on which the solar cell 12b is placed and (ii) the end surface opposite to the above end surface. The above light thus cannot be condensed upon the solar cell 12b. As a result, light that has been guided perpendicularly to the end surface opposite to the end surface on which the solar cell 12b is placed does not enter the solar cell 12b, which will decrease light use efficiency of the solar cell module 11b.

In view of the above problem, the solar cell module 1e should be arranged such that the portion opposite to the portion on which the solar cell 2 is placed is formed of a flat section as illustrated in FIG. 8, whereas any other flat section is not opposite to another flat section. With this arrangement, light that has entered the solar cell module 1e can be guided to the solar cell 2 efficiently.

(Solar Energy Generator Device)

A solar energy generator device of the present embodiment includes the above-described solar cell module 1. The solar energy generator device of the present embodiment may alternatively include, for example, a plurality of solar cell modules 1 and a storage battery that stores output from the solar cell modules 1. The solar energy generator device, which includes the solar cell module 1, is mountable to, for example, a window or roof of a structure or a window of an automobile. The solar energy generator device can, with use of the solar cell 2 having a small area, convert sunlight energy into electric power efficiently.

The present invention is not limited to the description of the embodiments above, but may be altered in various ways by a skilled person within the scope of the claims. Any embodiment based on a proper combination of technical means disclosed in different embodiments is also encompassed in the technical scope of the present invention.

### Recap of Embodiment

As described above, the solar cell module of the present invention may be arranged such that a portion opposite to the first portion is parallel to the first portion and has a flat surface.

With the above arrangement, light that has fallen upon the solar cell module along the direction perpendicular to the end surface on which the solar cell is placed is perpendicularly reflected by a portion that has a flat surface and that is opposite to the solar cell. The above light thus reaches the solar cell directly. In other words, light is guided to the solar cell through a minimum light guide distance. The above arrangement can thus minimize absorption loss that occurs while light is guided.

The solar cell module of the present invention may be arranged such that the bent surface has a zigzag shape in cross section along a surface direction of the condensing plate.

According to the above arrangement, light that has been guided to the bent surface of the condensing plate is reflected by that surface in a direction shifted from the direction of regular reflection. With this arrangement, almost all light that has been guided through the condensing plate ultimately reaches the solar cell, which increases light condensing property of the solar cell module.

The solar cell module of the present invention may be arranged such that the condensing plate has a round surface at (i) a portion at which adjacent ones of the plurality of intersecting surfaces meet and (ii) a bent portion at the bent surface.

According to the above arrangement, a portion of light that has entered the solar cell module which portion has been guided to (i) a corner of the solar cell module (that is, a portion at which end surfaces of the condensing plate meet) or (ii) a bent portion of a bent surface in the condensing plate is reflected by that corner or round surface of the bent portion. This arrangement can thus prevent the above light, which has been guided to a corner of the solar cell module or a bent portion of a bent surface, from being absorbed by that corner or bent portion. The above arrangement consequently allows the solar cell module to be higher in light condensing property and in light use efficiency.

In the case where (i) the solar cell module has a corner having a round surface or (ii) the condensing plate has a bent surface including a bent portion having a round surface, a reflecting plate is more easily bonded to an end surface of the condensing plate. Further, the above arrangement can prevent the solar cell module from being cracked or chipped while, for instance, it is being forwarded, and consequently allows the solar cell module to be handled more easily.

The solar cell module of the present invention may be arranged such that a first one of the plurality of intersecting surfaces which first intersecting surface includes a portion having the bent surface is substantially orthogonal to the light-obtaining surface.

The above arrangement does not disturb conditions under which light that has been guided through the condensing plate is totally reflected by the bent surface of the condensing plate. Thus, with the above arrangement, light that has entered the solar cell module can be reflected by the reflecting plate, which is provided to the end surfaces of the condensing plate, to be guided to the solar cell efficiently.

The solar cell module of the present invention may be arranged such that the bent portion at the bent surface is bent at an angle other than 90 degrees.

The above arrangement makes it possible to change the traveling direction of even light that has fallen upon a bent surface of the condensing plate. If the condensing plate has a bent surface having a bent portion with a bend angle of 90 degrees, light that has fallen upon the surface is reflected by a reflecting plate, and such light is unfortunately reflected twice by the bent surface of the condensing plate to travel along the direction opposite to the direction in which the light has fallen upon the surface. Thus, if the bent surface has a bent portion with a bend angle of 90 degrees, the traveling direction of light that has fallen upon the surface cannot be changed to a direction other than the direction opposite to the direction in which the light has fallen upon the surface. This means that in the case where the bent surface has a bent portion with an angle other than 90 degrees, the traveling direction of light that has fallen upon the surface can be changed, which in turn makes it possible to guide light to the solar cell efficiently.

The solar cell module of the present invention may be arranged such that the bent surface has a concave bent portion having a pitch of not smaller than 1 μm.

According to the above arrangement, light that has fallen upon a bent surface of the condensing plate can be reflected so that its traveling direction is changed. If the pitch of a concave bent portion is smaller than the wavelength of light that is guided through the condensing plate, the surface will not be able to reflect such light. The condensing plate of the present invention thus has a bent surface having a concave bent portion with a pitch of not smaller than 1 μm. This arrangement makes it possible to change the traveling direction of light when the light is reflected.

The embodiment and concrete examples of implementation discussed in the foregoing detailed explanation serve solely to illustrate the technical details of the present invention, which should not be narrowly interpreted within the limits of such embodiment and concrete examples, but rather may be applied in many variations within the spirit of the present invention, provided such variations do not exceed the scope of the patent claims set forth below.

### INDUSTRIAL APPLICABILITY

The present invention can provide a solar cell module that has (i) a design with a high degree of freedom and (ii) high condensing efficiency. The present invention can thus suitably be used as a solar energy generator system for use on, for example, (i) a window of a structure or automobile or (ii) a roof of a structure.

### REFERENCE SIGNS LIST

1, 1a through 1e, 11a, 11b solar cell module

2, 12a, 12b, 32 solar cell

3, 3a through 3d, 13a, 13b, 33 fluorescence condensing plate

4, 4a, 14a, 14b, 34 reflecting plate

6, 36 incident light

8 light guide plate

9 fluorescent material

20, 30 solar energy generator device

11 coating agent

12 sheet

13 adhesive

14 transparent sheet

21 solar panel

26 sunlight

1. A solar cell module comprising:
a condensing plate containing a fluorescent material, the condensing plate having (i) a light-obtaining surface and (ii) a plurality of intersecting surfaces each intersecting with the light-obtaining surface; and
a solar cell provided on at least a first portion of at least one of the plurality of intersecting surfaces,
a reflecting plate being provided on a portion of the plurality of intersecting surfaces which portion is other than the first portion,
at least a first part being present in which portions on each of which the solar cell is absent are opposite to each other,
at least one of any two mutually opposite portions selected from the first part having a bent surface.

2. The solar cell module according to claim 1,
wherein:
a portion opposite to the first portion is parallel to the first portion and has a flat surface.

3. The solar cell module according to claim 1,
wherein:
the bent surface has a zigzag shape in cross section along a surface direction of the condensing plate.

4. The solar cell module according to claim 1,
wherein:
the condensing plate has a round surface at (i) a portion at which adjacent ones of the plurality of intersecting surfaces meet and (ii) a bent portion at the bent surface.

5. The solar cell module according to claim 1,
wherein:
a first one of the plurality of intersecting surfaces which first intersecting surface includes a portion having the bent surface is substantially orthogonal to the light-obtaining surface.

6. The solar cell module according to claim 1,
wherein:
the bent portion at the bent surface is bent at an angle other than 90 degrees.

7. The solar cell module according to claim 1,
wherein:
the bent surface has a concave bent portion having a pitch of not smaller than 1 μm.

8. A solar energy generator device comprising:
a plurality of the solar cell module according to claim 1.
